(19) United States
(12) Patent Application Publication
(10) Pub. No.: US 2025/0237495 A1
(43) Pub. Date: Jul. 24, 2025

(54) DEPTH SENSOR

(71) Applicant: SK hynix Inc., Gyeonggi-do (KR)

(72) Inventor: Ji Hee HAN, Gyeonggi-do (KR)

(21) Appl. No.: 18/764,157

(22) Filed: Jul. 4, 2024

(30) Foreign Application Priority Data
Jan. 24, 2024 (KR) 10-2024-0010665

(51) Int. Cl. G01B 11/22; G01S 17/08

(52) U.S. Cl. CPC G01B 11/22; G01S 17/08

(57) ABSTRACT

Disclosed is a depth sensor including an extractor configured to, based on an input histogram, divide a plurality of time bins into a plurality of local periods and extract a plurality of peak count values corresponding to the plurality of local periods among a plurality of hit count values, the input histogram representing the plurality of hit count values according to the plurality of time bins, a remover configured to remove at least one invalid peak count value from among the plurality of peak count values and generate a plurality of local count values, and a selector configured to select a largest value among the plurality of local count values as a final peak count value.

### CROSS-REFERENCE TO RELATED APPLICATION(S)

This application claims priority under 35 U.S.C. § 119 to Korean Patent Application No. 10-2024-0010665, filed on Jan. 24, 2024, the disclosure of which is incorporated herein by reference in its entirety.

### BACKGROUND

### 1. Field

Various embodiments of the present disclosure relate to a semiconductor design technique, and more particularly, to a depth sensor that measures a depth.

### 2. Description of the Related Art

Light detection and ranging (LiDAR) is one of depth sensors used to measure a depth to a subject. LiDAR may accumulate a hit count value of a laser reflected from the subject into a plurality of time bins, and obtain the depth based on a time bin having the largest hit count value among the plurality of time bins.

### SUMMARY

Various embodiments of the present disclosure are directed to a depth sensor capable of accurately detecting peak information from a histogram for measuring a depth to a subject.

In accordance with an embodiment of the present disclosure, a depth sensor may include: an extractor configured to, based on an input histogram, divide a plurality of time bins into a plurality of local periods and extract a plurality of peak count values corresponding to the plurality of local periods among a plurality of hit count values, the input histogram representing the plurality of hit count values according to the plurality of time bins; a remover configured to remove at least one invalid peak count value from among the plurality of peak count values and generate a plurality of local count values; and a selector configured to select a largest value among the plurality of local count values as a final peak count value.

In accordance with an embodiment of the present disclosure, a depth sensor may include: an inflection point extractor configured to, based on an input histogram, divide a plurality of time bins into a plurality of local periods and generate a plurality of local count values corresponding to each inflection point in the plurality of local periods among a plurality of hit count values, the input histogram representing the plurality of hit count values according to the plurality of time bins; and selector configured to select a largest value among the plurality of local count values as a final peak count value.

In accordance with an embodiment of the present disclosure, a depth sensor may include: a histogram generator configured to generate an input histogram representing a plurality of hit count values according to a plurality of time-bins, based on a light detection signal corresponding to light reflected from a subject; a peak information generator configured to, based on the input histogram, select a final peak count value among the plurality of hit count values, check validity of the final peak count value, and generate peak information corresponding to the final peak count value; and a depth measurer configured to measure a depth to the subject based on the peak information.

### BRIEF DESCRIPTION OF THE DRAWINGS

FIG. 1 is a block diagram illustrating a configuration of a depth sensor in accordance with an embodiment of the present disclosure.

FIG. 2 is a block diagram illustrating a detailed configuration of a peak information generator illustrated in FIG. 1, in accordance with an embodiment of the present disclosure.

FIG. 3 is a block diagram illustrating a detailed configuration of an inflection point extractor illustrated in FIG. 2, in accordance with an embodiment of the present disclosure.

FIGS. 4 to 11 are diagrams for describing an operation of the depth sensor in accordance with an embodiment of the present disclosure.

### DETAILED DESCRIPTION

Various embodiments of the present disclosure are described below with reference to the accompanying drawings, in order to describe in detail the embodiments of the present disclosure so that those with ordinary skill in art to which the present disclosure pertains may easily carry out the technical spirit of the present disclosure.

It will be understood that when an element is referred to as being “connected to” or “coupled to” another element, the element may be directly connected to or coupled to the another element, or electrically connected to or coupled to the another element with one or more elements interposed therebetween. In addition, it will also be understood that the terms “comprises,” “comprising,” “includes,” and “including” when used in this specification do not preclude the presence of one or more other elements, but may further include or have the one or more other elements, unless otherwise mentioned. In the description throughout the specification, some components are described in singular forms, but the embodiments of the present disclosure are not limited thereto, and it will be understood that the components may be formed in plural.

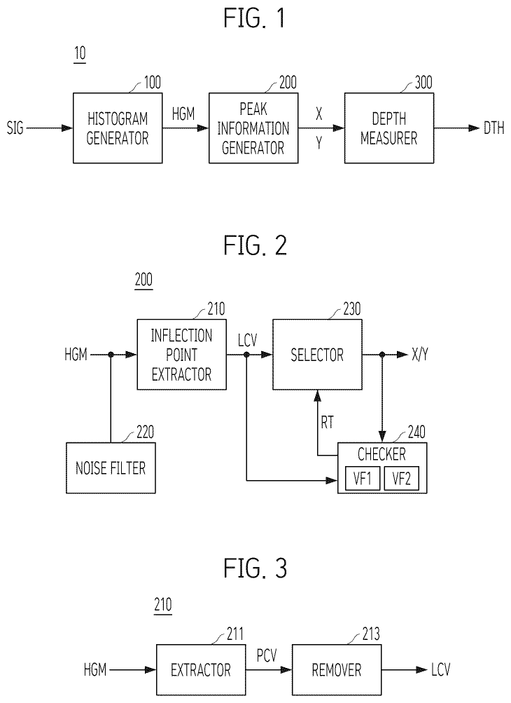

FIG. 1 is a block diagram illustrating a configuration of a depth sensor 10 in accordance with an embodiment of the present disclosure.

Referring to FIG. 1, the depth sensor 10 may include a histogram generator 100, a peak information generator 200, and a depth measurer 300.

The histogram generator 100 may generate an input histogram HGM representing a plurality of hit count values according to a plurality of time bins, based on a light detection signal SIG. The plurality of hit count values may refer to the cumulative number of inputs in which light (e.g., a laser) reflected from a subject is inputted to the depth sensor 10 according to a predetermined unit time. The plurality of time bins may correspond to the predetermined unit time, and be an indicator necessary when calculating a depth DTH to the subject. The light detection signal SIG may be an electrical signal generated in response to the light reflected from the subject.

The peak information generator 200 may select a final peak count value Y from among the plurality of hit count values, check validity of the final peak count value Y, and generate peak information X/Y using the final peak count value Y, based on the input histogram HGM. The peak information X/Y may include the final peak count value Y and a time bin number X corresponding to the final peak count value Y, among the plurality of time bins. The time bin number X, which is a time bin number at a point in time corresponding to the final peak count value Y among the plurality of time bins, may refer to the depth DTH to the subject.

The depth measurer 300 may measure the depth DTH to the subject based on peak information X/Y. For example, the depth measurer 300 may calculate the depth DTH by multiplying the time bin number X by the speed of light.

FIG. 2 is a block diagram illustrating a detailed configuration of the peak information generator 200 illustrated in FIG. 1, in accordance with an embodiment of the present disclosure.

Referring to FIG. 2, the peak information generator 200 may include an inflection point extractor 210, a noise filter 220, a selector 230, and a checker 240.

Based on the input histogram HGM, the inflection point extractor 210 may divide the plurality of time bins into a plurality of local periods and generate a plurality of local count values LCV corresponding to each inflection point in the plurality of local periods among the plurality of hit count values. Each of the plurality of local count values LCV may be a peak count value in each of the plurality of local periods.

The noise filter 220 may filter at least one noisy peak count value among the plurality of hit count values accumulated in the input histogram HGM. The noise filter 220 may include a Savitzky Golay filter. The noise filter 220 may be an optional component.

The selector 230 may compare the plurality of local count values LCV with one another, and select the largest value among the plurality of local count values LCV as the final peak count value Y. The selector 230 may select the final peak count value Y among the plurality of local count values LCV again based on a retry signal RT activated according to a result of checking the validity of the final peak count value Y. For example, the selector 230 may compare the other local count values, excluding the local count value previously selected as the final peak count value Y, among the plurality of local count values LCV, and select the largest value among the other local count values as the final peak count value Y again. The selector 230 may generate the peak information X/Y by using the final peak count value Y and the time bin number X corresponding to the final peak count value Y, among the plurality of time bins.

The checker 240 may check whether the final peak count value Y is a valid peak value. When the check result of the checker 240 indicates that the final peak count value Y is the valid peak value, the checker 240 may continuously deactivate the retry signal RT. When the check result of the checker 240 indicates that the final peak count value Y is an invalid peak value, the checker 240 may activate the retry signal RT. For example, the checker 240 may include at least one of a first checker VF1 and a second checker VF2.

The first checker VF1 may compare the final peak count value Y with at least one first reference value, and check the validity of the final peak count value Y according to the comparison result. For example, the at least one first reference value may include at least one peripheral value among the plurality of local count values LCV.

The second checker VF2 may compare the final peak count value Y with a second reference value, and check the validity of the final peak count value Y according to the comparison result. For example, the second reference value, which is a predetermined threshold value, may be a fixed global value.

FIG. 3 is a block diagram illustrating a configuration of the inflection point extractor 210 illustrated in FIG. 2, in accordance with an embodiment of the present disclosure.

Referring to FIG. 3, the inflection point extractor 210 may include an extractor 211 and a remover 213.

Based on the input histogram HGM, the extractor 211 may divide the plurality of time bins into the plurality of local periods and extract a plurality of peak count values PCV corresponding to the plurality of local periods, among the plurality of hit count values. Each of the plurality of peak count values PCV may be the peak count value in each of the plurality of local periods.

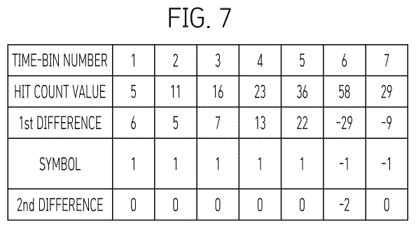

For example, the extractor 211 may calculate first difference values between adjacent hit count values among the plurality of hit count values according to the plurality of time bins, generate a plurality of symbol values SYMBOL corresponding to the plurality of hit count values, depending on whether the first difference values are a positive or negative number, and extract the plurality of peak count values PCV based on second difference values of adjacent symbol values according to the plurality of time bins among the plurality of symbol values SYMBOL (refer to FIG. 7).

The remover 213 may remove at least one invalid peak count value from the plurality of peak count values PCV, and generate the plurality of local count values LCV. For example, the remover 213 may select adjacent peak count values according to the plurality of time bins among the plurality of peak count values PCV, and remove, as the invalid peak count value, a smaller value among the adjacent peak count values.

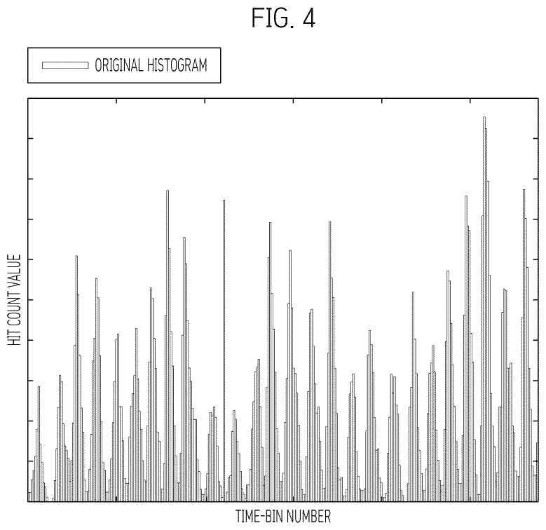

Hereinafter, an operation of the depth sensor 10 in accordance with an embodiment of the present disclosure, which has the above-described configuration, is described with reference to FIGS. 4 to 11.

FIG. 4 is a graph diagram for describing an operation of the histogram generator 100 illustrated in FIG. 1, in accordance with an embodiment of the present disclosure.

Referring to FIG. 4, the histogram generator 100 may generate the input histogram HGM based on the light detection signal SIG. The input histogram HGM may be an original histogram generated by the histogram generator 100. The input histogram HGM may generate the input histogram HGM by accumulating hit count values in each time bin number included in the plurality of time bins, based on the light detection signal SIG generated continuously during the time corresponding to the plurality of time bins.

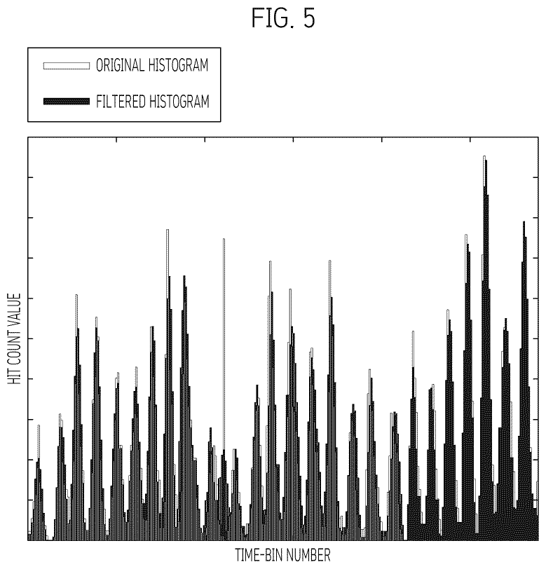

FIG. 5 is a graph diagram for describing an operation of the noise filter 220 illustrated in FIG. 2, in accordance with an embodiment of the present disclosure.

Referring to FIG. 5, the noise filter 220 may filter at least one noisy peak count value among the plurality of hit count values accumulated in the input histogram HGM. That is, the noise filter 220 may generate a filtered histogram including a plurality of filtered hit count values by reducing noise in the plurality of hit count values. Since the noise filter 220 does not necessarily need to be configured, it is described below as an example that the input histogram HGM corresponding to the original histogram is provided to the peak information generator 200.

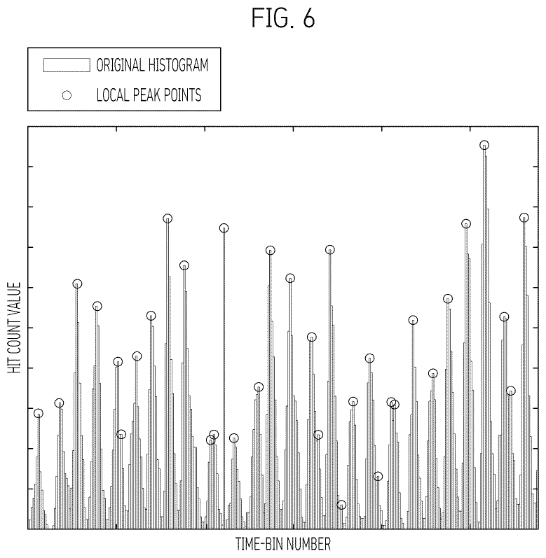

FIG. 6 is a graph diagram for describing an operation of the extractor 211 illustrated in FIG. 3, in accordance with an embodiment of the present disclosure, and FIG. 7 is a table for further describing the operation of the extractor 211 illustrated in FIG. 6, in accordance with an embodiment of the present disclosure. For example, FIG. 7 is a table representatively illustrating a process of extracting one peak count value in one local period among the plurality of local periods.

Referring to FIG. 6, the extractor 211 may divide the plurality of time bins into the plurality of local periods, and extract the plurality of peak count values PCV corresponding to the plurality of local periods among the plurality of hit count values, based on the input histogram HGM. Each of the plurality of peak count values PCV may be a peak count value in each of the plurality of local periods.

For example, referring to FIG. 7, the extractor 211 may calculate first difference values between the plurality of hit count values. For example, the extractor 211 may calculate a first difference value (11−5=6) between a first hit count value “5” and a second hit count value “11” between a first time bin number and a second time bin number adjacent to each other. The extractor 211 may generate the plurality of symbol values SYMBOL corresponding to the plurality of hit count values, depending on whether the first difference values are a positive or negative number. For example, the extractor 211 may generate a symbol value of “1” when the first difference value is a positive number, and generate a symbol value of “−1” when the first difference value is a negative number. The extractor 211 may calculate second difference values between the plurality of symbol values SYMBOL. For example, the extractor 211 may calculate a first difference value (1−1=0) between a first symbol value “1” and a second symbol value “1” between the first time bin number and the second time bin number adjacent to each other. The extractor 211 may extract the plurality of peak count values PCV based on the second difference values. For example, the extractor 211 may extract a hit count value, which corresponds to a second difference value “−2” among the plurality of hit count values, as a peak count value of a corresponding local period.

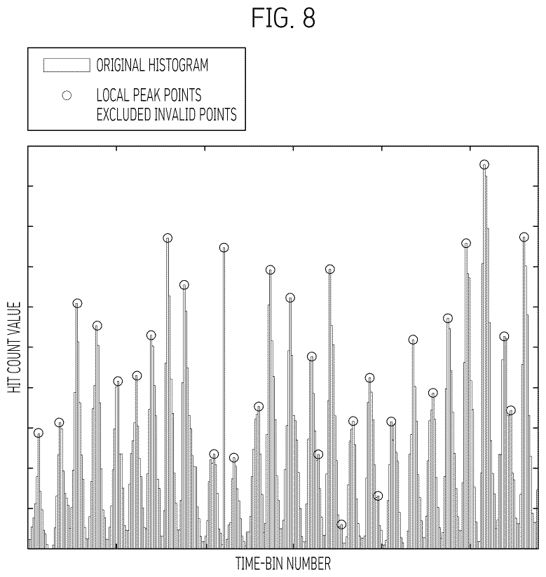

FIG. 8 is a graph diagram for describing an operation of the remover 213 illustrated in FIG. 3, in accordance with an embodiment of the present disclosure.

Referring to FIG. 8, the remover 213 may remove at least one invalid peak count value from the plurality of peak count values PCV, and generate the plurality of local count values LCV. For example, the remover 213 may select adjacent peak count values according to the plurality of time bins among the plurality of peak count values PCV, and remove, as an invalid peak count value, a smaller value among the adjacent peak count values. Whether the adjacent peak count values are adjacent to each other may be defined as in Equation 1 below.

$$[ Equation 1 ]$$

$$\vert local peak bin number ( i ) - local peak bin number ( i + 1 ) \vert < Th$$

Herein, “local peak bin number (i)” may refer to a time bin number (i.e., an i^{th} peak time bin number) corresponding to a peak count value of an i^{th} local period (where “i” is natural number greater than or equal to 1), “local peak bin number (i+1)” may refer to a time bin number (i.e., an (i+1)^{th} peak time bin number) corresponding to a peak count value of an (i+1)^{th} local period, and “TH” may refer to a threshold value indicating whether the adjacent peak count values are adjacent to each other.

That is, only when a difference value between the i^{th} peak time bin number and the (i+1)^{th} peak time bin number is smaller than the threshold value TH, the remover 213 may determine that the i^{th} peak time bin number and the (i+1)^{th} peak time bin number are adjacent to each other, and remove an invalid peak count value among the peak count value of the i^{th} local period and the peak count value of the (i+1)^{th} local period.

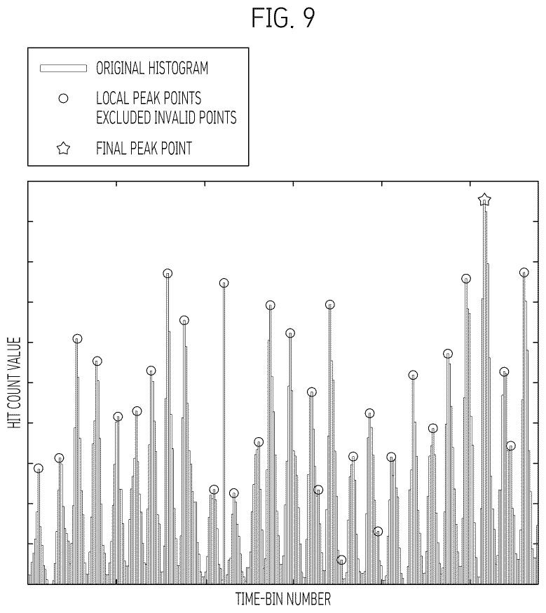

FIG. 9 is a graph diagram for describing an operation of the selector 230 illustrated in FIG. 2, in accordance with an embodiment of the present disclosure.

Referring to FIG. 9, the selector 230 may compare the plurality of local count values LCV with one another, and select the largest value among the plurality of local count values LCV as the final peak count value Y. The selector 230 may generate the peak information X/Y by using the final peak count value Y and the time bin number X corresponding to the final peak count value Y among the plurality of time bins.

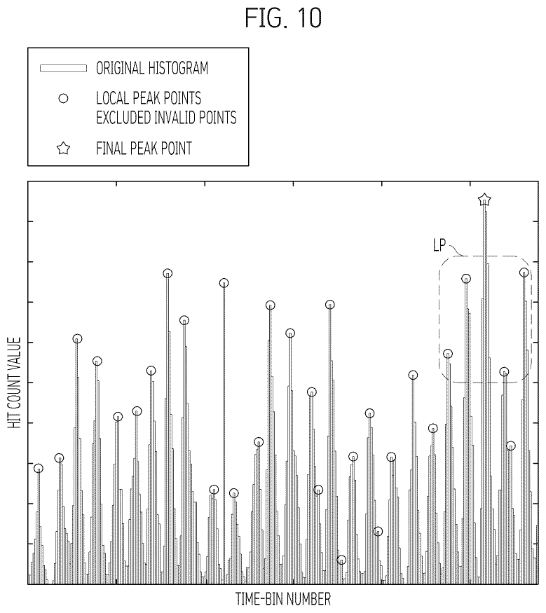

FIG. 10 is a graph diagram for describing an operation of the first checker VF1 illustrated in FIG. 2, in accordance with an embodiment of the present disclosure.

Referring to FIG. 10, the first checker VF1 may compare the final peak count value Y with at least one first reference value, and check the validity of the final peak count value Y according to the comparison result. For example, the at least one first reference value may include at least one peripheral value LP of the final peak count value Y among the plurality of local count values LCV.

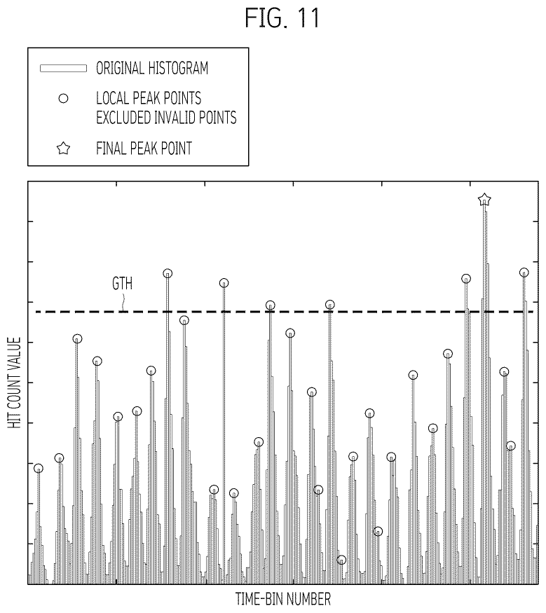

FIG. 11 is a graph diagram for describing an operation of the second checker VF2 illustrated in FIG. 2, in accordance with an embodiment of the present disclosure.

Referring to FIG. 11, the second checker VF2 may compare the final peak count value Y with a second reference value, and check the validity of the final peak count value Y according to the comparison result. For example, the second reference value, which is a predetermined threshold value, may be a fixed global value GTH.

According to an embodiment of the present disclosure, it is possible to accurately detect peak information from a histogram for measuring a depth to a subject. Particularly, according to an embodiment of the present disclosure, in a scheme of using both a coarse histogram and a fine histogram with different degrees of accuracy in order to measure the depth to the subject, when the embodiments of the present disclosure are applied to the fine histogram, more excellent detection accuracy can be expected.

According to an embodiment of the present disclosure, peak information may be accurately detected from a histogram for measuring a depth to a subject, which makes it possible to improve discrimination power of a depth sensor.

While the present disclosure has been illustrated and described with respect to specific embodiment, the disclosed embodiments are provided for the description, and not intended to be restrictive. Further, it is noted that the embodiments of the present disclosure may be achieved in various ways through substitution, change, and modification that fall within the scope of the following claims, as those skilled in the art will recognize in light of the present disclosure. Furthermore, the embodiments may be combined to form additional embodiments.

What is claimed is:

1. A depth sensor comprising:
an extractor configured to, based on an input histogram, divide a plurality of time bins into a plurality of local periods and extract a plurality of peak count values corresponding to the plurality of local periods, among a plurality of hit count values, the input histogram representing the plurality of hit count values according to the plurality of time bins;
a remover configured to remove at least one invalid peak count value from among the plurality of peak count values and generate a plurality of local count values; and
a selector configured to select a largest value among the plurality of local count values as a final peak count value.

2. The depth sensor of claim 1, wherein the extractor is configured to calculate difference values between the plurality of hit count values, and extract the plurality of peak count values corresponding to the plurality of local periods based on the difference values.

3. The depth sensor of claim 2, wherein the extractor is configured to generate a plurality of symbol values corresponding to the plurality of hit count values depending on whether the difference values are positive or negative numbers, and extract the plurality of peak count values based on difference values between the plurality of symbol values.

4. The depth sensor of claim 1, wherein the remover is configured to select adjacent peak count values according to the plurality of time bins, among the plurality of peak count values, and remove a smaller value among the adjacent peak count values as an invalid peak count value.

5. The depth sensor of claim 1, further comprising a noise filter configured to filter at least one noisy peak count value among the plurality of hit count values accumulated in the input histogram.

6. The depth sensor of claim 5, wherein the noise filter includes a Savitzky Golay filter.

7. The depth sensor of claim 1, further comprising a checker configured to check whether the final peak count value is a valid peak value.

8. The depth sensor of claim 7, wherein:
the checker includes at least one of a first checker and a second checker,
the first checker is configured to compare the final peak count value with at least one peripheral value, which is at least one value among the plurality of local count values, and check validity of the final peak count value according to a comparison result, and
the second checker is configured to compare the final peak count value with a global value, which is a predetermined threshold value, and check the validity of the final peak count value according to the comparison result.

9. A depth sensor comprising:
an inflection point extractor configured to, based on an input histogram, divide a plurality of time bins into a plurality of local periods and generate a plurality of local count values corresponding to each inflection point in the plurality of local periods, among a plurality of hit count values, the input histogram representing the plurality of hit count values according to the plurality of time bins; and
a selector configured to select a largest value among the plurality of local count values as a final peak count value.

10. The depth sensor of claim 9, wherein the inflection point extractor includes:
an extractor configured to divide, based on the input histogram, the plurality of time bins into the plurality of local periods and extract a plurality of peak count values corresponding to the plurality of local periods, among the plurality of hit count values; and
a remover configured to remove at least one invalid peak count value among the plurality of peak count values and generate the plurality of local count values.

11. The depth sensor of claim 10, wherein the extractor is configured to calculate difference values between the plurality of hit count values, and extract the plurality of peak count values corresponding to the plurality of local periods based on the difference values.

12. The depth sensor of claim 11, wherein the extractor is configured to generate a plurality of symbol values corresponding to the plurality of hit count values depending on whether the difference values are positive or negative numbers, and extract the plurality of peak count values based on difference values between the plurality of symbol values.

13. The depth sensor of claim 10, wherein the remover is configured to select adjacent peak count values according to the plurality of time bins, among the plurality of peak count values, and remove, as an invalid peak count value, a smaller value among the adjacent peak count values.

14. The depth sensor of claim 9, further comprising a noise filter configured to filter at least one noisy peak count value among the plurality of hit count values accumulated in the input histogram.

15. The depth sensor of claim 14, wherein the noise filter includes a Savitzky Golay filter.

16. The depth sensor of claim 9, further comprising a checker configured to check whether the final peak count value is a valid peak value.

17. The depth sensor of claim 16, wherein:
the checker includes at least one of a first checker and a second checker,
the first checker is configured to compare the final peak count value with at least one peripheral value, which is at least one value among the plurality of local count values, and check validity of the final peak count value according to a comparison result, and
the second checker is configured to compare the final peak count value with a global value, which is a predetermined threshold value, and check the validity of the final peak count value according to the comparison result.

18. A depth sensor comprising:
a histogram generator configured to generate an input histogram representing a plurality of hit count values according to a plurality of time-bins, based on a light detection signal corresponding to light reflected from a subject;
a peak information generator configured to, based on the input histogram, select a final peak count value among the plurality of hit count values, check validity of the final peak count value, and generate peak information corresponding to the final peak count value; and
a depth measurer configured to measure a depth to the subject based on the peak information.

19. The depth sensor of claim 18, wherein the peak information generator includes:
an inflection point extractor configured to divide, based on the input histogram, the plurality of time bins into a plurality of local periods and generate a plurality of local count values corresponding to each inflection point in the plurality of local periods, among the plurality of hit count values;
a selector configured to compare the plurality of local count values with one another and select a largest value among the plurality of local count values as a final peak count value; and
a checker configured to check the validity of the final peak count value.

20. The depth sensor of claim 19, wherein the inflection point extractor includes:
an extractor configured to divide, based on the input histogram, the plurality of time bins into the plurality of local periods and extract a plurality of peak count values corresponding to the plurality of local periods, among the plurality of hit count values; and
a remover configured to remove at least one invalid peak count value among the plurality of peak count values to generate the plurality of local count values.
